(19) United States
(12) Patent Application Publication
(10) Pub. No.: US 2011/0031575 A1
(43) Pub. Date: Feb. 10, 2011

(54) SOLID-STATE IMAGE SENSOR

(75) Inventors: Atsuo NAKAGAWA, Kyoto (JP); Ichiroh Murakami, Shizuoka (JP); Masanori Murakami, Shizuoka (JP)

Correspondence Address: McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/905,820

(22) Filed: Oct. 15, 2010

Related U.S. Application Data
(63) Continuation of application No. PCT/JP2010/000296, filed on Jan. 20, 2010.

(30) Foreign Application Priority Data
Jun. 5, 2009 (JP) 2009-136453

(51) Int. Cl. H01L 31/0232

(52) U.S. Cl. 257/432; 257/E31.127

(57) ABSTRACT

A solid-state image sensor includes first and second pixels formed on a semiconductor substrate. The first pixel includes: a first photoelectric conversion region located in an upper portion of the semiconductor substrate; a first transfer electrode; a light-shield film covering the first transfer electrode and having a first opening on the first photoelectric conversion region; and a first anti-reflection film located on the first photoelectric conversion region and, when viewed in plan, within the first opening so as not to overlap the first light-shield film. The second pixel includes: a second photoelectric conversion region located in an upper portion of the semiconductor substrate; a second transfer electrode; the light-shield film covering the second transfer electrode and having a second opening on the second photoelectric conversion region; and a second anti-reflection film located on the second photoelectric conversion region and continuously extending to a portion on the second transfer electrode.

### CROSS-REFERENCE TO RELATED APPLICATION

This is a continuation of PCT International Application PCT/JP2010/000296 filed on Jan. 20, 2010, which claims priority to Japanese Patent Application No. 2009-136453 filed on Jun. 5, 2009. The disclosures of these applications including the specifications, the drawings, and the claims are hereby incorporated by reference in their entirety.

### BACKGROUND

In a solid-state image sensor such as a charge coupled device (CCD), when light enters an n-type semiconductor region formed in a p-type silicon substrate, signal charge is generated in this n-type semiconductor region. A video signal can be obtained from the signal charge generated in each pixel in this manner.

FIG. 4 is a cross-sectional view illustrating an example of a conventional solid-state image sensor typically described in Japanese Patent Publication No. 2001-015724, and shows a region including a pixel provided on a p-type semiconductor substrate 101. In FIG. 4, transfer electrodes 104 are formed above the semiconductor substrate 101 with an insulating film 103 interposed therebetween. A light-receiving portion 102 which is an n-type semiconductor region is provided in a surface portion of the semiconductor substrate 101, and is located between the two transfer electrodes 104.

An anti-reflection film 109 is provided above the light-receiving portion 102 with the insulating film 103 interposed therebetween. The anti-reflection film 109 has a refractive index higher than that of the insulating film 103 and lower than that of the semiconductor substrate 101, and reduces the reflectivity of incident light on the surface of the semiconductor substrate 101 in a wavelength range of visible light.

In addition, another insulating film 105 is provided to cover the transfer electrodes 104 and the anti-reflection film 109. A light-shield film 106 is provided over the transfer electrodes 104 with the insulating film 105 interposed therebetween, and has an opening above the light-receiving portion 102. A passivation film 107 is further provided to cover the insulating film 105 and the light-shield film 106. An insulating layer 108 is formed on the passivation film 107.

The presence of the anti-reflection film 109 in such a solid-state image sensor increases the amount of incident light on the light-receiving portion 102, thereby increasing light-receiving sensitivity.

### SUMMARY

However, in the structure of the solid-state image sensor illustrated in FIG. 4, a spurious signal (smearing) occurs more easily than in a structure including no anti-reflection film 109, and thus, reduction of this smearing is needed.

In view of this problem, a solid-state image sensor capable of reducing smearing while maintaining light-receiving sensitivity will be described hereinafter.

To achieve the object described above, the inventors of the present disclosure studied a cause of an increase in smearing in the solid-state image sensor including the anti-reflection film 109 as illustrated in FIG. 4. In this study, the inventors focused on the fact that a gap E between the light-receiving portion 102 and the light-shield film 106 is large because of the interposition of the anti-reflection film 109 near the outer periphery of the light-receiving portion 102.

When light enters a pixel, especially when light obliquely enters a pixel, the light leaks into the transfer electrodes 104 or transfer regions under the transfer electrodes 104 through the gap E to cause smearing in some cases. In other cases, charge leaks into the transfer regions through the gap E to also cause smearing. In these cases, as the gap E increases, the amount of leakage of light or charge increases, thereby increasing the influence of smearing.

Based on the foregoing findings, the inventors of the present disclosure found that the size of the gap can be reduced by preventing the anti-reflection film from being located between the light-receiving portion and the light-shield film.

Specifically, in an aspect of the present disclosure, a solid-state image sensor includes first and second pixels formed on a semiconductor substrate. The first pixel includes: a first photoelectric conversion region located in an upper portion of the semiconductor substrate and configured to generate charge by photoelectric conversion; a first transfer electrode located at a side of the first photoelectric conversion region and on the semiconductor substrate; a light-shield film covering the first transfer electrode and having a first opening on the first photoelectric conversion region; and a first anti-reflection film located on the first photoelectric conversion region and, when viewed in plan, within the first opening so as not to overlap the light-shield film. The second pixel includes: a second photoelectric conversion region located in an upper portion of the semiconductor substrate and configured to generate charge by photoelectric conversion; a second transfer electrode located at a side of the second photoelectric conversion region and on the semiconductor substrate; the light-shield film covering the second transfer electrode and having a second opening on the second photoelectric conversion region; and a second anti-reflection film located on the second photoelectric conversion region and continuously extending to a portion on the second transfer electrode.

In such a solid-state image sensor, the first anti-reflection film is provided not to overlap the light-shield film (i.e., located within the first opening of the light-shield film when viewed in plan). Accordingly, the gap between the light-shield film and the first photoelectric conversion region is small, thereby reducing leakage of light and charge through the gap. Thus, the first anti-reflection film can reduce reflection of incident light, thereby increasing the amount of incident light on the first photoelectric conversion region. In addition, smearing can be reduced.

Further, the second anti-reflection film continuously extending to a portion on the second transfer electrode is provided on the second photoelectric conversion region. Accordingly, in the second pixel, the second anti-reflection film is provided over the entire second photoelectric conversion region, and this configuration is preferable in terms of sensitivity than that of the first pixel including the first anti-reflection film within the first opening. Leakage of light to be a cause of smearing is less likely to occur with respect to light with a larger wavelength. Thus, the first pixel for primarily reducing smearing (i.e., the pixel including the anti-reflection film located within the opening) and the second pixel for primarily increasing sensitivity (i.e., the pixel including another anti-reflection film located on the entire photoelectric conversion region) can be selected depending on the wavelength of light incident on the pixel. In the second pixel, the second anti-reflection film extends to a position on the second transfer electrode, and thus, the withstand voltage between the second transfer electrode and the light-shield film can be increased.

A distance between an outer periphery of the first anti-reflection film and an inner periphery of the first opening of the light-shield film may be 50 nm or less.

A region in which the first anti-reflection film is not provided on the first photoelectric conversion region causes a decrease in sensitivity of the solid-state image sensor. Thus, such a region is preferably as narrow as possible. For example, the above distance may be 50 nm or less.

The solid-state image sensor may further include a first insulating film covering the first anti-reflection film and the first transfer electrode and located under the light-shield film, and the distance between the outer periphery of the first anti-reflection film and the inner periphery of the first opening of the light-shield film may be larger than or equal to a thickness of the first insulating film.

If the light-shield film extends to a portion near the outer periphery of the first anti-reflection film, the light-shield film in this portion rises toward a side opposite the first photoelectric conversion region. This rising portion of the light-shield film prevents light from entering the first photoelectric conversion region, and does not reduce leakage of light and charge into the first transfer electrode. To prevent this problem, the light-shield film is formed within a range at a distance larger than or equal to the thickness of the first insulating film formed on the first anti-reflection film from the outer periphery of the first anti-reflection film, thereby preventing the rising described above.

A distance in which the light-shield film extends inward from an outer periphery of the first photoelectric conversion region is preferably larger than or equal to a distance from an upper surface of the first photoelectric conversion region to an opposing lower surface of the light-shield film.

Such a configuration is preferable because leakage of light into the first transfer electrode and the first transfer region under the first transfer electrode is reduced.

In the solid-state image sensor, the first pixel may include a first color filter located above the first photoelectric conversion region and configured to perform color separation on incident light, the second pixel may include a second color filter located above the second photoelectric conversion region and configured to perform color separation on incident light, and the first color filter may be a color filter configured to transmit light with a shorter wavelength than the second color filter.

Leakage of light to be a cause of smearing is more likely to occur with respect to light with a smaller wavelength. Thus, the second pixel receiving light with a shorter wavelength preferably has a configuration in which the anti-reflection film is provided within the opening to reduce leakage of light.

The first color filter may be a color filter configured to transmit light with a wavelength of blue.

The second color filter may be a color filter configured to transmit light of a wavelength of red or green.

In the case where the color filters of the pixels perform color separation into three colors of red, green, and blue, light with a wavelength of blue has the shortest wavelength. Thus, the pixel corresponding to light with a wavelength of blue is preferably a pixel (i.e., the first pixel) having the structure for primarily reducing smearing.

The solid-state image sensor may further include a second insulating film covering the first photoelectric conversion region and the first transfer electrode and located under the first anti-reflection film.

In the solid-state image sensor, the first anti-reflection film may not be interposed between the first photoelectric conversion region and the light-shield film, and the second anti-reflection film may be interposed between the second photoelectric conversion region and the light-shield film.

This configuration can increase the withstand voltage between the second transfer electrode and the light-shield film.

A third anti-reflection film may be provided on the first transfer electrode. This configuration can increase the withstand voltage between the first transfer region and the light-shield film. In addition, since the third anti-reflection film can be formed simultaneously with the first anti-reflection film, thereby preventing an increase in the number of processes.

A first distance from an upper surface of the first photoelectric conversion region to an opposing lower surface of the light-shield film may be smaller than a second distance from an upper surface of the second photoelectric conversion region to an opposing lower surface of the light-shield film.

In this configuration, the amount of light leaking from a portion under the light-shield film into the first transfer region in the first pixel is smaller than the amount of light leaking from a portion under the light-shield film into the second transfer region in the second pixel, thereby reducing a spurious signal.

In the solid-state image sensor, the first distance may be in the range from 50 nm to 100 nm, both inclusive, and the second distance may be in the range from 100 nm to 150 nm, both inclusive.

Specific distances may be as follows:

The second anti-reflection film may cover an entire surface of the second photoelectric conversion region.

This configuration can further increase the light-receiving sensitivity of the second pixel. The second pixel may have a light-receiving sensitivity higher than that of the first pixel.

Each of the first anti-reflection film and the second anti-reflection film may be made of a silicon nitride film.

The light-shield film may be made of tungsten or aluminum.

The semiconductor substrate may be made of a silicon substrate, the second insulating film may be made of a silicon oxide film, and each of the first anti-reflection film and the second anti-reflection film may be a film having a refractive index higher than that of the silicon oxide film and lower than the silicon substrate.

Materials and dimensions of the components may be determined in the foregoing manner.

In the solid-state image sensor as described above, the anti-reflection film is provided within the opening of the light-shield film located on the photoelectric conversion region. This configuration can reduce the distance between the light-shield film and the photoelectric conversion region, thereby reducing leakage of light or charge as a cause of smearing.

### BRIEF DESCRIPTION OF THE DRAWINGS

FIG. 1 is a cross-sectional view schematically illustrating a main portion of an example solid-state image sensor according to a first embodiment of the present disclosure.

FIG. 2 is a plan view illustrating the solid-state image sensor of FIG. 1, and schematically shows an arrangement of a plurality of pixels.

FIG. 3 is a plan view illustrating an example solid-state image sensor according to a second embodiment of the present disclosure, and schematically shows an arrangement of a plurality of pixels.

FIG. 4 is a view illustrating a conventional solid-state image sensor.

### DETAILED DESCRIPTION

Embodiments of the present disclosure will be described hereinafter with reference to the drawings. Each of the embodiments is shown as an example for describing the configuration and advantages of a solid-state image sensor according to the present disclosure, and is not limited to the following description. Various modifications and changes are included within the scope of the present disclosure.

### First Embodiment

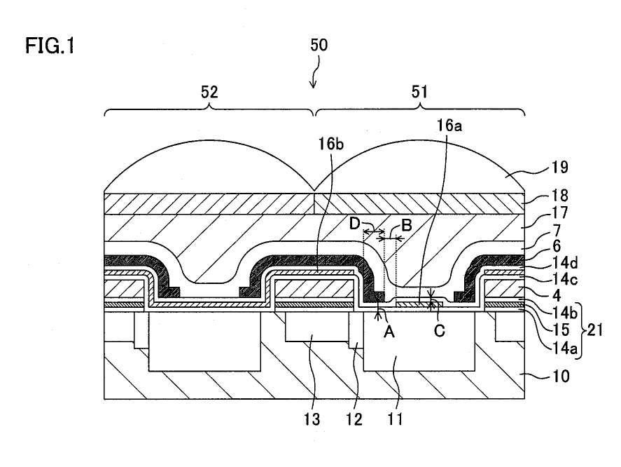

A first embodiment of the present disclosure will be described hereinafter. FIG. 1 is a cross-sectional view illustrating a solid-state image sensor 50 according to the first embodiment. FIG. 1 particularly shows a region including two of a plurality of pixels arranged on a p-type silicon substrate 10.

As illustrated in FIG. 1, in the solid-state image sensor 50, a plurality of photoelectric conversion regions 11 made of n-type semiconductor regions and a plurality of transfer regions 13 made of n-type semiconductor regions are alternately arranged in an upper portion of the p-type silicon substrate (a semiconductor substrate) 10. A p-type semiconductor layer of the p-type silicon substrate 10 is left between an end of each of the photoelectric conversion regions 11 and the adjacent one of the transfer regions 13, and serves as a readout region for reading charge generated in the photoelectric conversion region 11 to the transfer region 13. An isolation region 12 of a p⁺-type semiconductor region is provided between another end (i.e., an end opposite to the readout region) of each of the photoelectric conversion regions 11 and one of the transfer regions 13 adjacent to the end of the photoelectric conversion region 11. A region including one photoelectric conversion region 11 and one transfer region 13 between two isolation regions 12 serves as one pixel.

Transfer electrodes 4 are provided above the p-type silicon substrate 10 and cover the transfer regions 13 with an ONO insulating film 21 interposed therebetween. The ONO insulating film 21 is a three-layer insulating film, i.e., is an insulating film with a so-called ONO structure made of a thin first silicon oxide film 14a covering the surface of the transfer regions 13, a silicon nitride film 15 provided on the first silicon oxide film 14a, and a second silicon oxide film 14b provided on the silicon nitride film 15. Instead of the ONO insulating film 21, another insulating film such as a single-layer film of a silicon oxide film may be used.

A third silicon oxide film 14c is provided as an insulating film continuously covering the surfaces of the photoelectric conversion regions 11 and side surfaces and upper surfaces of the transfer electrodes 4.

In a pixel 51 among the above-mentioned pixels, a first anti-reflection film 16a is formed above the photoelectric conversion regions 11 with the third silicon oxide film 14c interposed therebetween. The first anti-reflection film 16a is made of a silicon nitride film having a refractive index higher than that of the silicon oxide film and lower than that of the silicon substrate.

As an insulating film covering the first anti-reflection film 16a and the transfer electrodes 4, a fourth silicon oxide film 14d is provided. A light-shield film 6 made of tungsten or aluminum is provided on the fourth silicon oxide film 14d. The light-shield film 6 covers side surfaces and upper surfaces of the transfer electrodes 4 to shield the transfer electrodes 4 from incident light, and has an opening on the photoelectric conversion regions 11 not to prevent light from entering the photoelectric conversion regions 11.

In the pixel 51, the first anti-reflection film 16a is located within the opening of the light-shield film 6 when viewed in plan. In other words, when viewed in plan, the first anti-reflection film 16a does not overlap the light-shield film 6 (i.e., does not underlie the light-shield film 6).

On the other hand, in another pixel 52, a second anti-reflection film 16b is provided above the photoelectric conversion regions 11 with the third silicon oxide film 14c interposed therebetween. The second anti-reflection film 16b is covered with the fourth silicon oxide film 14d. The light-shield film 6 is provided on the fourth silicon oxide film 14d to cover the transfer electrodes 4 and have an opening on the photoelectric conversion regions 11.

It should be noted that the second anti-reflection film 16b has a structure different from that of the first anti-reflection film 16a. Specifically, the second anti-reflection film 16b covers the entire surfaces of the photoelectric conversion regions 11, extends to cover the side surfaces and the upper surfaces of the transfer electrodes 4 located on both sides of each of the photoelectric conversion regions 11, and has a portion (i.e., a portion underlying the light-shield film 6) which overlaps the light-shield film 6 in plan view.

In these pixels, a passivation film 7 is provided to cover the photoelectric conversion regions 11 and the light-shield film 6. A planarized layer 17 is provided on the passivation film 7. Color filters 18 for color separation of incident light are provided on the planarized layer 17. Further, microlenses 19 associated with the respective photoelectric conversion regions 11 are provided on the color filters 18.

The presence of the first anti-reflection film 16a and the second anti-reflection film 16b can increase sensitivity in each of the pixel 51 and the pixel 52. In general, about 30% of incident light as visible light is reflected at the interface between a silicon substrate and a silicon oxide film, causing a decrease in sensitivity. This high reflectivity at the interface between the silicon substrate and the silicon oxide film is due to a large difference between a refractive index (about 3 to about 4) of silicon and a refractive index (about 1.45) of the silicon oxide film.

To prevent the problem described above, a film having a refractive index higher than that of the silicon oxide film and lower than that of the substrate is formed as an anti-reflection film, thereby increasing the incidence rate of light on silicon. As a result, sensitivity can be increased. For example, Japanese Patent Publication No. 2000-12817 shows that formation of an anti-reflection film achieves a 23% increase in sensitivity.

In the solid-state image sensor 50 as described above, a spurious signal (smearing) can be more significantly reduced in the pixel 51 than in the pixel 52, and sensitivity can be more significantly increased in the pixel 52 than in the pixel 51 in the manner which will be described below.

First, in each pixel, part of the light-shield film 6 is located above the peripheral portions of the photoelectric conversion regions 11. When charge or light leaks into the transfer regions 13 through the gap between the lower surface of the light-shield film 6 and the upper surfaces of the photoelectric conversion regions 11 in this region, a spurious signal can be generated.

In the pixel 51, the first anti-reflection film 16a is not located under the light-shield film 6. Accordingly, the distance A between the photoelectric conversion regions 11 and the light-shield film 6 (i.e., the distance from the upper surfaces of the photoelectric conversion regions 11 to the opposing lower surface of the light-shield film 6) is the total thickness of the third silicon oxide film 14c and the fourth silicon oxide film 14d, and is about 50 nm to about 100 nm. On the other hand, in the pixel 52, the second anti-reflection film 16b in addition to the third silicon oxide film 14c and the fourth silicon oxide film 14d is interposed between the photoelectric conversion regions 11 and the light-shield film 6. Since the thickness of the second anti-reflection film 16b is about 50 nm, the total thickness thereof is about 100 nm to about 150 nm.

In this manner, in the pixel 51, the distance between the light-shield film 6 and the photoelectric conversion regions 11 is smaller than that in the pixel 52 by the thickness (e.g., about 50 nm) of the anti-reflection film. Accordingly, the amount of light or charge leaking into the transfer regions 13 from this region decreases, thereby reducing a spurious signal (smearing).

To prevent an overlap between the first anti-reflection film 16a and the light-shield film 6, the outer periphery of the first anti-reflection film 16a is spaced by a distance B from the inner periphery of the opening of the light-shield film 6. If this region including no anti-reflection film (i.e., the distance B) increases, incident light on the photoelectric conversion regions 11 might decrease to reduce sensitivity. For this reason, the distance B is preferably as small as possible, and is preferably 50 nm or less.

However, since the fourth silicon oxide film 14d is provided on the first anti-reflection film 16a, if the distance B is too small, an end of the light-shield film 6 disadvantageously rises toward a side opposite the photoelectric conversion regions 11. This rise might inhibit entering of light into the photoelectric conversion regions 11, and leakage of light or charge into the transfer regions 13 cannot be sufficiently reduced. Thus, to prevent this rise, the distance B is smaller than the thickness C of the fourth silicon oxide film 14d.

If a distance D of a region in which the light-shield film 6 overlies the photoelectric conversion regions 11 is small, incident light (especially light obliquely entering) easily leaks into the transfer regions 13. Thus, the distance D is preferably large to a certain degree, and is preferably larger than the distance A between the photoelectric conversion regions 11 and the light-shield film 6. When the distance D is equal to the distance A, light leakage to an incident angle of 45° can be prevented. Thus, as an example, the distance D is preferably larger than the distance A. In the pixel 51, the distance A is about 50 nm to about 100 nm, for example, and thus, the distance D is preferably larger than this range.

On the other hand, in the pixel 52, the second anti-reflection film 16b covers the entire surface of the photoelectric conversion region 11, and extends to the peripheral transfer regions 13. Accordingly, the distance between the photoelectric conversion region 11 and the light-shield film 6 is larger than that in the pixel 51 by the thickness of the second anti-reflection film 16b, and a spurious signal cannot be reduced as compared to the pixel 51. However, since the second anti-reflection film 16b covers the entire surface of the photoelectric conversion region 11, a larger amount of light enters the photoelectric conversion region 11 than in the pixel 51, and thus, light-receiving sensitivity is higher than that in the pixel 51.

In general, light with a shorter wavelength more easily passes through a narrow gap. Thus, in the case of a solid-state image sensor including color filters 18 of three primary colors of B (blue), G (green), and R (red), for example, light of B having a shorter wavelength than light of R and light of G easily enters the transfer regions 13 through the gaps between the photoelectric conversion regions 11 and the light-shield film 6. Accordingly, a spurious signal (smearing) due to leakage of light from these regions is larger in a B pixel (i.e., a pixel including a color filter 18 for B, and the same for a R pixel and a G pixel hereinafter) than in a R pixel and a G pixel. Thus, the B pixel has the configuration of the pixel 51 in which the first anti-reflection film 16a is located within the opening of the light-shield film 6, and each of the R and G pixels has the configuration of the pixel 52 in which the second anti-reflection film 16b is provided over the entire surface of the photoelectric conversion region 11. In this manner, a spurious signal is primarily reduced in the B pixel in which a spurious signal (smearing) is easily generated, and sensitivity is primarily increased in the R and G pixels in which a spurious signal is less easily generated than in the B pixel.

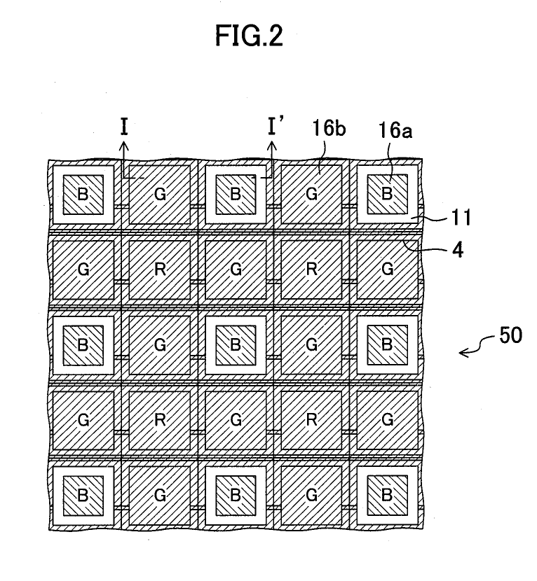

An example of such a configuration of the color filters will be further described with reference to FIG. 2. FIG. 2 is a plan view illustrating the solid-state image sensor 50, and shows an example of an arrangement of a plurality of pixels (i.e., B pixels, G pixels, and R pixels) in the solid-state image sensor 50 including color filters of three primary colors of B, G, and R. The cross section taken along line I-I′ in FIG. 2 corresponds to FIG. 1 (where dimensions of components in FIG. 2, however, do not necessarily match those in FIG. 1).

As illustrated in FIG. 2, the color filters 18 in the solid-state image sensor 50 have a configuration (i.e., a so-called primary-color Bayer pattern) in which four pixels made of one B pixel, one R pixel, and two G pixels are defined as one unit, and such units are arranged in an array.

When viewed in plan as in FIG. 2, the first anti-reflection film 16a in the B pixel is formed to be within the opening of the light-shield film 6. That is, this configuration corresponds to that in the pixel 51 in FIG. 1. In the pixel 51, no anti-reflection film is provided under the light-shield film 6 at the sides of the transfer regions 13. Accordingly, the distance between the photoelectric conversion regions 11 and the light-shield film 6 is reduced by a value corresponding to the thickness (e.g., about 50 nm) of the anti-reflection film. This configuration can reduce leakage of light into the transfer regions 13, resulting in reduction of a spurious signal.

On the other hand, in each of the R pixel and the G pixel, the second anti-reflection film 16b is formed to cover the transfer regions 13 and the entire surface of the photoelectric conversion region 11, and this configuration corresponds to that in the pixel 52 in FIG. 1. In the pixel 52, the entire surface of the photoelectric conversion region 11 is covered with the anti-reflection film, thereby increasing sensitivity. As compared to B light which easily causes smearing because of a short wavelength thereof, smearing is less likely to occur with respect to R light and G light having larger wavelengths than that of B light. Accordingly, smearing is not a significant problem in R and G pixels with structures for primarily increasing sensitivity. It may be, of course, possible to provide the structure of the pixel 52 only for the R pixels in order to primarily increase sensitivity and the structure of the pixel 51 for G and B pixels in order to reduce smearing.

The extension of the second anti-reflection film 16b to portions between the transfer regions 13 and the light-shield film 6 can increase the withstand voltage between the transfer regions 13 and the light-shield film 6.

A method for fabricating a solid-state image sensor 50 will be described hereinafter.

First, photoelectric conversion regions 11 which are n-type semiconductor regions, transfer regions 13 which are also n-type semiconductor regions, and isolation regions 12 which are p⁺-type semiconductor regions are formed in upper portions of a p-type silicon substrate 10. The isolation regions 12 isolate each pixel including one of the photoelectric conversion regions 11 and one of the transfer regions 13 from each other. In each pixel, a portion of the p-type silicon substrate 10 which is a p-type semiconductor layer is interposed between the photoelectric conversion region 11 and the transfer region 13. Each of these regions may be formed by, for example, implanting an impurity.

Next, an ONO insulating film 21 is formed to cover the photoelectric conversion regions 11, the isolation regions 12, the transfer regions 13, and readout regions.

To form the ONO insulating film 21, first, a first silicon oxide film 14a is formed as a first-layer insulating film. The first silicon oxide film 14a is preferably a film grown by low-pressure chemical vapor deposition (LPCVD) and then subjected to heat treatment at a higher temperature than the deposition temperature. Then, a silicon nitride film 15 is formed as a second-layer insulating film on the first silicon oxide film 14a. The silicon nitride film 15 is preferably formed by plasma CVD. Thereafter, a second silicon oxide film 14b as a third-layer insulating film is formed on the silicon nitride film 15. The second silicon oxide film 14b is preferably formed by, for example, LPCVD. Through these processes, an ONO insulating film 21 having a stacked structure of the silicon oxide film/the silicon nitride film/the silicon oxide film, i.e., a so-called ONO structure, is formed on the p-type silicon substrate 10.

The ONO insulating film 21 is located under transfer electrodes 4 which will be formed in a later process. The insulating film does not need to have the ONO structure. Instead of forming the ONO insulating film 21, the silicon nitride film 15 and the second silicon oxide film 14b may be omitted so that a single-layer insulating film made of only the first silicon oxide film 14a is provided.

Next, a polysilicon layer for forming transfer electrodes 4 is formed on the ONO insulating film 21. Subsequently, through processes including resist formation and etching, portions of the polysilicon layer and the ONO insulating film 21 located on the photoelectric conversion regions 11 are removed, thereby forming transfer electrodes 4 through patterning above the transfer regions 13 with the ONO insulating film 21 interposed therebetween. In this manner, the upper surfaces of the photoelectric conversion regions 11 are exposed.

Then, a third silicon oxide film 14c is formed as an insulating film continuously covering the photoelectric conversion regions 11 and the transfer electrodes 4. The third silicon oxide film 14c is preferably formed by a process, e.g., LPCVD, in which the step coverage is uniform and the thickness can be precisely controlled.

Thereafter, a silicon nitride film to be an anti-reflection film is formed by, for example, plasma CVD to cover the third silicon oxide film 14c. To increase sensitivity in the visible light range, the thickness of the silicon nitride film is preferably about 50 nm. Subsequently, through processes including resist formation and etching, the silicon nitride film is patterned, thereby forming a second anti-reflection film 16b extending from a position on each of the photoelectric conversion regions 11 to a position on an adjacent one of the transfer electrodes 4, and a first anti-reflection film 16a located within space above the photoelectric conversion regions 11 (i.e., located within the photoelectric conversion regions 11 when viewed in plan, and within an opening of a light-shield film 6 which will be described later).

In patterning the silicon nitride film into the first anti-reflection films 16a by plasma etching above the photoelectric conversion regions 11, damage in the plasma etching might form an intermediate level near the silicon interface on the photoelectric conversion regions 11. Accordingly, dark current increases in a pixel including the first anti-reflection film 16a (e.g., the pixel 51 in FIG. 1). On the other hand, in a pixel including the second anti-reflection film 16b extending to the transfer electrodes 4 (e.g., the pixel 52 shown in FIG. 1), patterning is not performed above the photoelectric conversion regions 11, and thus, formation of the intermediate level and an increase in dark current caused by the formation of the intermediate level do not occur. Consequently, the amount of dark current differs among pixels (i.e., depending on the difference in structure between the pixel 51 and the pixel 52).

In general, a light-shielded pixel is provided in an effective pixel region of an image sensor in order to obtain a signal to be used as a reference of the black level. Such a pixel called an optical black (OB) part preferably has a structure of a pixel having a large dark current, i.e., the structure of the pixel 51 including the first anti-reflection film 16a located within a space above the photoelectric conversion regions 11.

Then, a fourth silicon oxide film 14d is formed as an insulating film by, for example, LPCVD to cover the first anti-reflection film 16a and the second anti-reflection film 16b.

Subsequently, a light-shield film 6 is formed. The light-shield film 6 is formed by forming a film made of, for example, aluminum or tungsten by CVD, and then removing portions above the photoelectric conversion regions 11 by, for example, etching. In this manner, the light-shield film 6 having openings above the photoelectric conversion regions 11 is formed. In each of the openings of the light-shield film 6, the first anti-reflection film 16a or the second anti-reflection film 16b is exposed.

Thereafter, a passivation film 7 is formed. The passivation film 7 is formed to cover the light-shield film 6 and the first and second anti-reflection films 16a and 16b exposed above the photoelectric conversion regions 11. At this time, since the underlying film has a step difference between portions on the transfer electrodes 4 and the photoelectric conversion regions 11, the passivation film 7 is recessed toward the p-type silicon substrate 10 above the photoelectric conversion regions 11.

Then, a planarized layer 17 is formed on the passivation film 7. The planarized layer 17 is preferably formed as a film having a refractive index higher than that of the passivation film 7. Then, since the passivation film 7 is recessed above the photoelectric conversion regions 11, the planarized layer 17 has an advantage of a lens which is convex downward. Specifically, incident light can be focused at a position near the p-type silicon substrate 10 so that light entering the photoelectric conversion regions 11 can be increased. As a result, sensitivity can be increased, and light leaking into the transfer regions 13 can be reduced, thereby reducing smearing.

Thereafter, color filters 18 for color separation of incident light are formed on the planarized layer 17. The color filters 18 may be formed by semiconductor processes including lithography and etching. Subsequently, microlenses 19 are formed on the color filters 18 in association with the respective photoelectric conversion regions 11. In this manner, incident light on the solid-state image sensor 50 can efficiently enter the photoelectric conversion regions 11 of the pixels. To form the microlenses 19, for example, a silicon nitride film is formed on the entire surface of the planarized layer 17, then a resist pattern is formed on the silicon nitride film, and then the resist pattern is dry etched, thereby forming a silicon nitride film into the microlenses 19.

Through the foregoing processes, a solid-state image sensor 50 can be fabricated.

### Second Embodiment

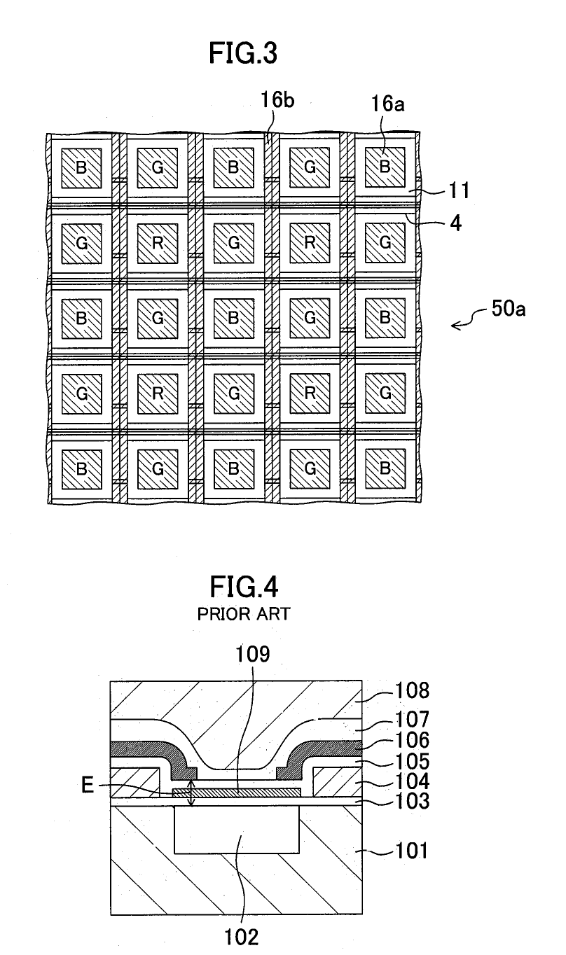

A solid-state image sensor 50a according to a second embodiment of the present disclosure will be described. FIG. 3 is a plan view illustrating a main portion of the solid-state image sensor 50a.

The solid-state image sensor 50a of this embodiment has a structure similar to that of the solid-state image sensor 50 of the first embodiment. One of main differences is that the first anti-reflection film 16a is formed in the opening of the light-shield film 6 not only in B pixels but also in R pixels and G pixels. That is, in the solid-state image sensor 50a, all the B, G, and R pixels have the structure of the pixel 51 (see, FIG. 1) in which the first anti-reflection film 16a is located within the opening of the light-shield film 6 above the photoelectric conversion region 11.

In addition, a material film 16c made of the same material as that for an anti-reflection film 26a is formed on transfer electrodes 4.

In the solid-state image sensor 50a having the above-described structure, a spurious signal (smearing) can be reduced in all the B, G, and R pixels, in the same manner as for the B pixels (i.e., the pixel 51) in the first embodiment. Specifically, the absence of the first anti-reflection film 16a between the light-shield film 6 and the photoelectric conversion regions 11 can reduce the distance between the light-shield film 6 and the photoelectric conversion regions 11 at the sides of the transfer electrodes 4, and reduces light leakage from this region into the transfer regions 13.

Further, the material film 16c located between the transfer electrodes 4 and the light-shield film 6 can increase the withstand voltage between the transfer electrodes 4 and the light-shield film 6. The material film 16c may be formed by, for example, a process in which in patterning a silicon nitride film above the photoelectric conversion regions 11 to form the first anti-reflection film 16a, this patterning is performed above the transfer electrodes 4. In this manner, the solid-state image sensor 50a can be fabricated without an increase in the number of processes for forming the material film 16c.

In the first embodiment and the second embodiment, primary-color color filters of B, G, and R are employed. Alternatively, color filters of complementary colors may be employed, for example. In such a case, the structure for primarily reducing smearing (i.e., the structure of the pixel 51) and the structure for primarily increasing sensitivity (i.e., the structure of the pixel 52) can be selected depending on the wavelength of light incident on the pixel.

A solid-state image sensor according to the present disclosure is useful as a solid-state image sensor in which an anti-reflection film is formed depending on the type of a pixel, and thereby, reduction of smearing and increase in sensitivity can be adjusted for each pixel to obtain a high-quality image.

What is claimed is:

1. A solid-state image sensor, comprising:
first and second pixels formed on a semiconductor substrate, wherein
the first pixel includes
a first photoelectric conversion region located in an upper portion of the semiconductor substrate and configured to generate charge by photoelectric conversion,
a first transfer electrode located at a side of the first photoelectric conversion region and on the semiconductor substrate,
a light-shield film covering the first transfer electrode and having a first opening on the first photoelectric conversion region, and
a first anti-reflection film located on the first photoelectric conversion region and, when viewed in plan, within the first opening so as not to overlap the first light-shield film, and
the second pixel includes
a second photoelectric conversion region located in an upper portion of the semiconductor substrate and configured to generate charge by photoelectric conversion,
a second transfer electrode located at a side of the second photoelectric conversion region and on the semiconductor substrate,
the light-shield film covering the second transfer electrode and having a second opening on the second photoelectric conversion region, and
a second anti-reflection film located on the second photoelectric conversion region and continuously extending to a portion on the second transfer electrode.

2. The solid-state image sensor of claim 1, wherein a distance between an outer periphery of the first anti-reflection film and an inner periphery of the first opening of the light-shield film is 50 nm or less.

3. The solid-state image sensor of claim 1, further comprising a first insulating film covering the first anti-reflection film and the first transfer electrode and located under the light-shield film, and
the distance between the outer periphery of the first anti-reflection film and the inner periphery of the first opening of the light-shield film is larger than or equal to a thickness of the first insulating film.

4. The solid-state image sensor of claim 1, wherein a distance in which the light-shield film extends inward from an outer periphery of the first photoelectric conversion region is larger than or equal to a distance from an upper surface of the first photoelectric conversion region to an opposing lower surface of the light-shield film.

5. The solid-state image sensor of claim 1, wherein
the first pixel includes a first color filter located above the first photoelectric conversion region and configured to perform color separation on incident light,
the second pixel includes a second color filter located above the second photoelectric conversion region and configured to perform color separation on incident light, and
the first color filter is a color filter configured to transmit light with a shorter wavelength than the second color filter.

6. The solid-state image sensor of claim 5, wherein the first color filter is a color filter configured to transmit light with a wavelength of blue.

7. The solid-state image sensor of claim 6, wherein the second color filter is a color filter configured to transmit light of a wavelength of red or green.

8. The solid-state image sensor of claim 1, further comprising a second insulating film covering the first photoelectric conversion region and the first transfer electrode and located under the first anti-reflection film.

9. The solid-state image sensor of claim 1, wherein the first anti-reflection film is not interposed between the first photoelectric conversion region and the light-shield film, and
the second anti-reflection film is interposed between the second photoelectric conversion region and the light-shield film.

10. The solid-state image sensor of claim 1, wherein a third anti-reflection film is provided on the first transfer electrode.

11. The solid-state image sensor of claim 1, wherein a first distance from an upper surface of the first photoelectric conversion region to an opposing lower surface of the light-shield film is smaller than a second distance from an upper surface of the second photoelectric conversion region to an opposing lower surface of the light-shield film.

12. The solid-state image sensor of claim 11, wherein
the first distance is in the range from 50 nm to 100 nm, both inclusive, and
the second distance is in the range from 100 nm to 150 nm, both inclusive.

13. The solid-state image sensor of claim 1, wherein the second anti-reflection film covers an entire surface of the second photoelectric conversion region.

14. The solid-state image sensor of claim 1, wherein the second pixel has a light-receiving sensitivity higher than that of the first pixel.

15. The solid-state image sensor of claim 1, wherein each of the first anti-reflection film and the second anti-reflection film is made of a silicon nitride film.

16. The solid-state image sensor of claim 1, wherein the light-shield film is made of tungsten or aluminum.

17. The solid-state image sensor of claim 8, wherein the semiconductor substrate is made of a silicon substrate,
the second insulating film is made of a silicon oxide film, and
each of the first anti-reflection film and the second anti-reflection film is a film having a refractive index higher than that of the silicon oxide film and lower than the silicon substrate.
